(19) United States
(12) Patent Application Publication
(10) Pub. No.: US 2026/0218371 A1
(43) Pub. Date: Jul. 30, 2026

(54) TUNGSTEN-SILICON-NITROGEN SPUTTERING TARGET, ASSEMBLY AND METHOD OF MAKING

(71) Applicant: Solstice Advanced Materials US, Inc., Morris Plains, NJ (US)

(72) Inventors: Xiaodan Wu, Spokane, WA (US); Rashmi Mohanty, Liberty Lake, WA (US)

(21) Appl. No.: 19/441,608

(22) Filed: Jan. 6, 2026

Related U.S. Application Data
(60) Provisional application No. 63/749,029, filed on Jan. 24, 2025.

(51) Int. Cl. C23C 14/34; B22F 3/15

(52) U.S. Cl. CPC C23C 14/3414; B22F 3/15; B22F 2301/20

(57) ABSTRACT

A sputtering target assembly includes a WₓSi_{100-x-y}N_{y} sputtering target wherein x is 40-65 at. % and y is 10-30 at. %, wherein the sputtering target has a density of at least 90% theoretical. A method of making a sputtering target assembly is also included.

### CROSS-REFERENCE TO RELATED APPLICATION

This application claims priority to Provisional Application No. 63/749,029, filed Jan. 24, 2025, which is herein incorporated by reference in its entirety.

### TECHNICAL FIELD

The present disclosure relates to sputtering target assemblies comprising tungsten, silicon and nitrogen (WSiN). WSiN sputtering targets can be used in the fabrication of semiconductors.

### BACKGROUND

Physical vapor deposition methodologies are used extensively for forming thin films of material over a variety of substrates. One area of importance for such deposition technology is semiconductor fabrication. A diagrammatic view of a portion of an exemplary physical vapor deposition (“PVD”) apparatus 8 is shown in FIG. 1. In one configuration, a sputtering target assembly 10 comprises a backing plate 12 having a target 14 bonded thereto. A substrate 18 such as a semiconductive material wafer is within the PVD apparatus 8 and provided to be spaced from the target 14. A surface 16 of target 14 is a sputtering surface. As shown, the target 14 is disposed above the substrate 18 and is positioned such that sputtering surface 16 faces substrate 18. In operation, sputtered material 22 is displaced from the sputtering surface 16 of target 14 and used to form a coating (or thin film) 20 over substrate 18.

Tungsten-silicon-nitrogen (WSiN) films can be used in the fabrication of semiconductors. In some embodiments, W—Si—N films can be used as a diffusion barrier for copper interconnection to prevent copper diffusion. In other embodiments, W—Si—N films may be used in gallium arsenide (GaAs) field effect transistors (MESFET).

Previously, W—Si—N films were formed by co-sputtering tungsten and silicon targets under a nitrogen atmosphere. A W—Si—N sputtering target would form a W—Si—N film using a single sputtering target, improving efficiency of the fabrication process.

### SUMMARY

In Embodiment 1 a process for manufacturing a sputtering target assembly includes combining silicon powder, tungsten powder and silicon nitride powder to form a mixed powder; hot pressing the mixed powder at a temperature at or below 1400° C. to form a semi-sintered part; and hot isostatic pressing the semi-sintered part at a temperature of 1650° C. or greater and a pressure over 20 ksi to form a sputtering target having a composition WₓSi_{100-x-y}N_{y} wherein x is 40-65 at. % and y is 10-30 at. %, and a density of at least 90% theoretical.

In Embodiment 2, the process of Embodiment 1, wherein a weight percentage of nitrogen in the mixed powder is within ±1% of a weight percentage of nitrogen in the sputtering target.

In Embodiment 3, the process of Embodiment 1, wherein a weight percentage of nitrogen in the mixed powder is within ±0.5% of a weight percentage of nitrogen in the sputtering target.

In Embodiment 4, the process of Embodiment 1, wherein a weight percentage of nitrogen in the mixed powder is within ±0.25% of a weight percentage of nitrogen in the sputtering target.

In Embodiment 5, the process of Embodiment 4, wherein a weight percentage of silicon and a weight percentage of tungsten in the mixed powder is within ±0.25% of a weight percentage of silicon and a weight percentage of tungsten in the sputtering target.

In Embodiment 6, the process of Embodiment 1 and further comprising bonding the sputtering target to a backing plate.

In Embodiment 7, the process of Embodiment 6, wherein bonding the sputtering target to the backing plate includes bonding the sputtering target to the backing plate by a solder bond.

In Embodiment 8, a sputtering target assembly includes a WₓSi_{100-x-y}N_{y} sputtering target wherein x is 40-65 at. % and y is 10-30 at. %, and wherein the sputtering target has a density of at least 90% theoretical.

In Embodiment 9, the sputtering target assembly of Embodiment 8, wherein the WₓSi_{100-x-y}N_{y} sputtering target has a purity of at least 99.95%.

In Embodiment 10, the sputtering target assembly of Embodiment 8, wherein the WₓSi_{100-x-y}N_{y} sputtering target is bonded to a backing plate.

In Embodiment 11, the sputtering target assembly of Embodiment 10, wherein the backing plate is a copper or copper alloy backing plate.

In Embodiment 12, the sputtering target assembly of Embodiment 8, wherein the WₓSi_{100-x-y}N_{y} sputtering target is solder bonded to a backing plate.

While multiple embodiments are disclosed, still other embodiments of the present invention will become apparent to those skilled in the art from the following detailed description, which shows and describes illustrative embodiments of the invention. Accordingly, the drawings and detailed description are to be regarded as illustrative in nature and not restrictive.

### BRIEF DESCRIPTION OF THE DRAWINGS

FIG. 1 is a schematic illustration of a sputtering apparatus.

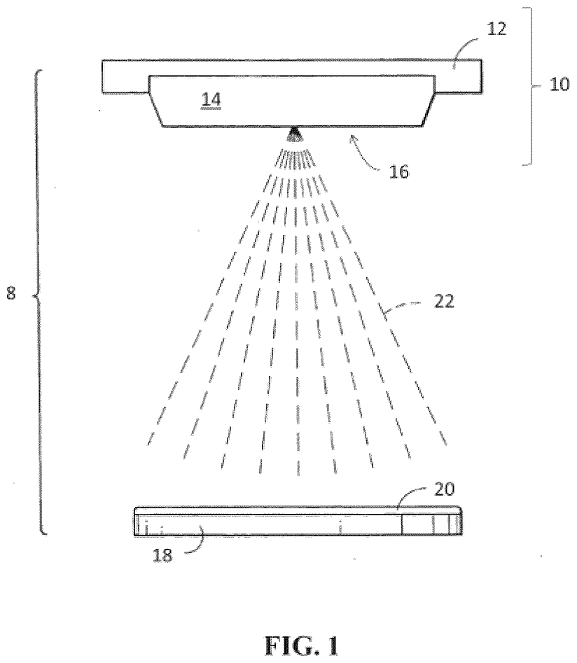

FIG. 2 is a block diagram of an exemplary tungsten-silicon-nitrogen sputtering target manufacturing process.

FIG. 3A and FIG. 3B are scanning electron microscopy (SEM) images of a fracture surface.

FIG. 4 is an electron backscatter diffraction (EBSD) color coded orientation map.

FIG. 5 is a grain size histogram as measured by EBSD.

FIG. 6A is a pole figure plot.

FIG. 6B is an inverse pole figure plot.

FIG. 7A and FIG. 7B are scanning electron microscopy (SEM) images.

FIG. 8 is the phase identification results (at %).

### DETAILED DESCRIPTION

Disclosed herein is a tungsten-silicon-nitrogen (WSiN) sputtering target. In some embodiments, the sputtering target is a monolithic sputtering target in which the sputtering surface and the backing plate are a single piece. In other embodiments, the sputtering target is bonded to a backing plate.

The sputtering target comprises x atomic percent (at. %) tungsten, y at. % nitrogen and 100-x-y at. % silicon (WₓSi_{100-x-y}N_{y}). In some embodiments, x is from about 40 to about 65. In some embodiments, y is from about 10 to about 30. One skilled in the art will recognize that the sputtering target includes inevitable impurities.

In some embodiments, the sputtering target has a density of at least 90%, at least 91%, or at least 92%. In some embodiments, the density can be measured by Archimedes method.

One skilled in the art will recognize that the sputtering target includes inevitable impurities. In some embodiments, the sputtering target has a purity of at least 99.9% pure. In some embodiments, the sputtering target has a purity of at least 99.95% pure.

In some embodiments, the sputtering target has a small average grain size. The average grain size can be measured by EBSD analysis. In some embodiments, the average grain size is less than about 25 microns, less than about 20 microns or less than about 15 microns. In some embodiments, the average grain size is greater than about 1 micron, about 3 microns or about 5 microns. In some embodiments, the average grain size is between about 1 micron and about 15 microns.

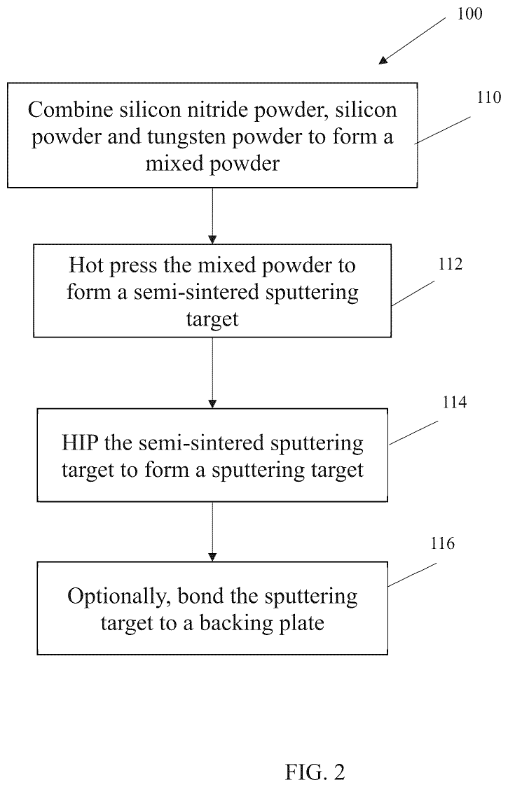

FIG. 2 is a block diagram of process 100 for forming a WSiN target. In step 110, silicon nitride (Si₃N₄) powder, silicon (Si) powder and tungsten (W) powder are mixed together to form a mixed powder. In some embodiments, the amount of each respective powder is determined by based on the amount of tungsten, silicon and nitrogen desired in the finished sputtering target and the dimensions of the sputtering target. In some embodiments, the amount of powders is determined so that the sputtering target comprises x at. % tungsten, y at. % nitrogen and 100-x-y at. % silicon (WₓSi_{100-x-y}N_{y}), wherein x is from about 40 to about 65 and y is from about 10 to about 30.

In step 112, the mixed powder is semi-sintered to form a sputtering target. In one embodiment, the mixed powder is semi-sintered by hot pressing the mixed powder at temperature equal to or less than about 1400° C. The hot press chamber is operated under a vacuum.

In step 114, the semi-sintered sputtering target is hot isostatic pressed (HIP) at a temperature at or above 1650° C. or a temperature at or above 1700° C. and a pressure at or above 20 ksi. In some embodiments, the HIP process increases the density of the sputtering target without significantly impacting the composition of the sputtering target.

The resulting sputtering target has a composition and density as described herein. At high temperatures, tungsten and silicon nitride react to form nitrogen gas as shown by reactions (1) and (2).

$$5 W + {Si}_{3} {N}_{4} = {W}_{5} {Si}_{3} + 2 {N}_{2} ( g ) \qquad ( 1 )$$

$$3 W + 2 {Si}_{3} {N}_{4} = 3 {WSi}_{2} + 4 {N}_{2} ( g ) \qquad ( 2 )$$

Reaction (1) thermodynamically occurs at temperatures greater than about 1434° C. and reaction (2) occurs at temperatures greater than about 1607° C. The formation of nitrogen gas is not desired because it results in loss of nitrogen in the sputtering target. That is, the resulting alloy will have a lower nitrogen content than desired.

By semi-sintering the powder at temperatures at or below approximately 1400° C. semi-sinters the nitrogen to the other materials and avoids formation of nitrogen gas. However, hot pressing at this temperature can produce a sputtering target with a density lower than described herein.

It has been found that performing a second sintering process at a higher temperature results in a sputtering target with a density of at least 90%. In some embodiments, the density is at least 94%. While not wishing to bond by theory, it is believed that nitrogen bonds to the tungsten and/or silicon during the first hot pressing step. Because the first hot pressing step is conducted at temperatures at or below 1400° C., nitrogen gas is not formed and the composition of the alloy is substantially the same as the original powder. Next, the semi-sintered sputtering target is subjected to a HIP process at a higher temperature, such as above 1650° C. Because the nitrogen is bonded to the tungsten and/or silicon, nitrogen gas does not form or substantially does not form and the composition of the alloy is substantially the same as the original powder.

In some embodiments, the composition of the sputtering target is within ±1 wt. %, 0.5 wt. % or 0.25 wt. % of the original powder. For example, the wt. % tungsten in the mixed powder of step 110 can be within ±1%, 0.5% or 0.25% of the tungsten composition of the sputtering target of step 114. Similarly, the wt. % silicon and the wt. % nitrogen in the mixed powder can be within #1%, 0.5% or 0.25% of the silicon and nitrogen compositions, respectively, of the sputtering target.

In optional step 116, the sputtering target is bonded to a backing plate. In some embodiments, the sputtering target is bonded to the backing plate by a solder bond. In some embodiments, the backing plate can be a copper or a copper alloy backing plate. In some embodiments, a solder, such as an indium, tin or tin alloy solder can bond the sputtering target to the backing plate.

As used herein, “about” can mean ±1%, ±2%, ±3%, ±4% or ±5%. All percentages are in weight percent (wt. %) unless noted otherwise.

Various modifications and additions can be made to the exemplary embodiments discussed without departing from the scope of the present invention. For example, while the embodiments described above refer to particular features, the scope of this invention also includes embodiments having different combinations of features and embodiments that do not include all of the above-described features.

### Example 1

A 60W25Si15N (60 atomic percent (at. %) tungsten, 25 at. % silicon and 15 at. % nitrogen) small scale sample was prepared by mixing 562.30 grams (g) tungsten powder, 19.60 g silicon powder and 26.78 g silicon nitride powder. The small sample had a diameter of 3.2 inches (88.9 mm) and a thickness of 0.35 inch (8.89 mm). The mixed powder was hot pressed at 1400° C. and under vacuum to form the semi-sintered small-scale sample. The hot press temperature was at or below 1400° C. to avoid formation of nitrogen gas. The density after vacuum hot press was 85%. To increase the density, the hot isostatic pressing (HIP) was conducted at 1740° C. and 25.25 ksi. After the HIP processing, the density of the sample was measured as 12.38 g/cm³. The calculated theoretical density is 13.202 g/cm³. Thus, the density was 94%.

After HIP, the sample composition was measured using standard ICP-OES. The measured composition of the sample is provided in Table 1.

TABLE 1
Composition of Example 1

| | Measured wt % | Nominal |
|---|---|---|
| 60W25Si15N (at %) | of Sample | Composition wt % |
| W | 92.5 | 92.38 |
| Si | 5.53 | 5.86 |
| N | 1.8 | 1.76 |

As shown in Table 1, the composition of the sample was substantially similar to the calculated composition (the nominal composition). This indicates that the process can have good control of the composition.

The purity of the sample was 3N5 or 99.95% purity.

The transverse rupture strength (TRS) of the sample was tested as per ASTM B528-16. The average TRS was 36.3 ksi. The low TRS value indicates that the 60W25Si15N material is brittle, there is a high risk of cracking during the machining process.

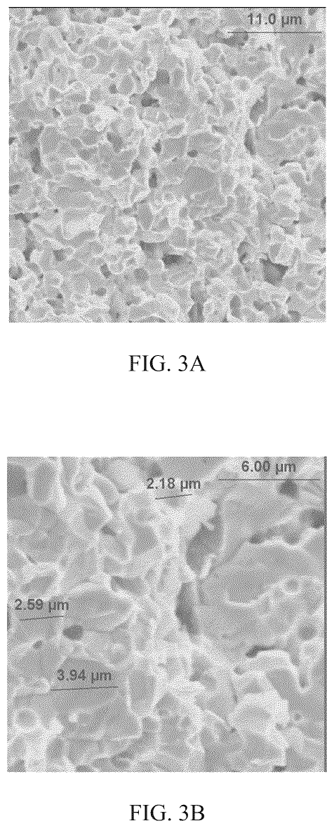

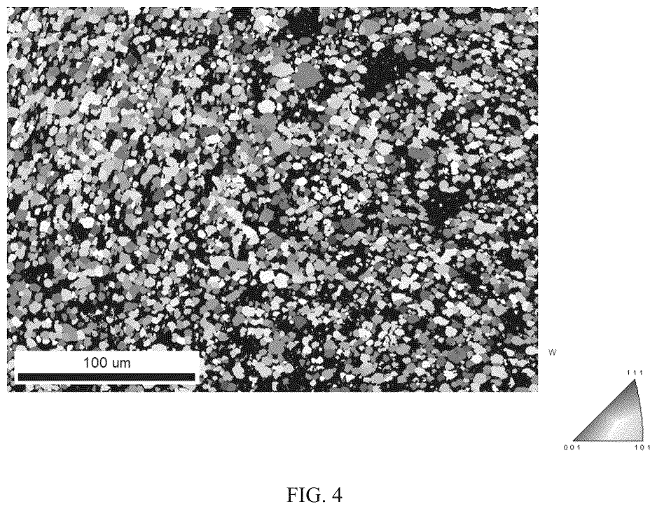

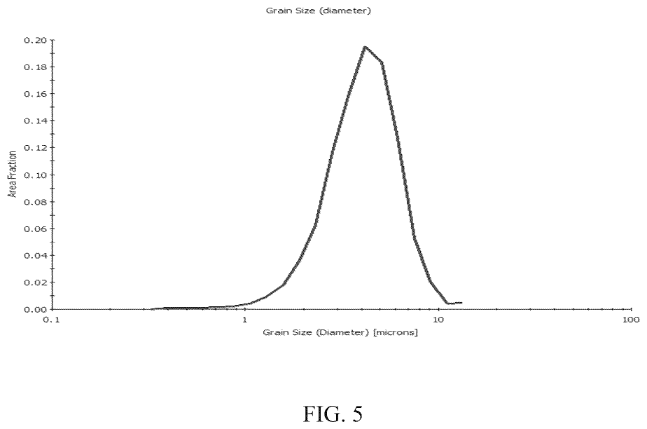

The surface of the sample was observed by scanning electron microscopy (SEM). FIGS. 3A and 3B are SEM images of the fracture surface, showing a typical characteristic of brittle material. The EBSD analysis was conducted to measure the grain size and texture. FIG. 4 is the EBSD Color Coded Orientation Map. FIG. 5 shows the grain size histogram and data measured by EBSD. The grain size data is provided in Table 2.

TABLE 2
Grain Size of Example 1

| Grain size | Micron (μm) |
|---|---|
| Min | 0.3 |
| Max | 13.5 |
| Avg. | 4.3 |
| Std. Dev. | 1.8 |

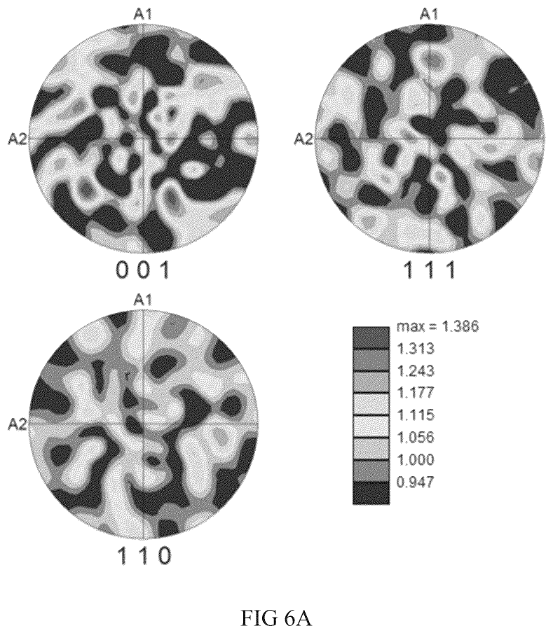

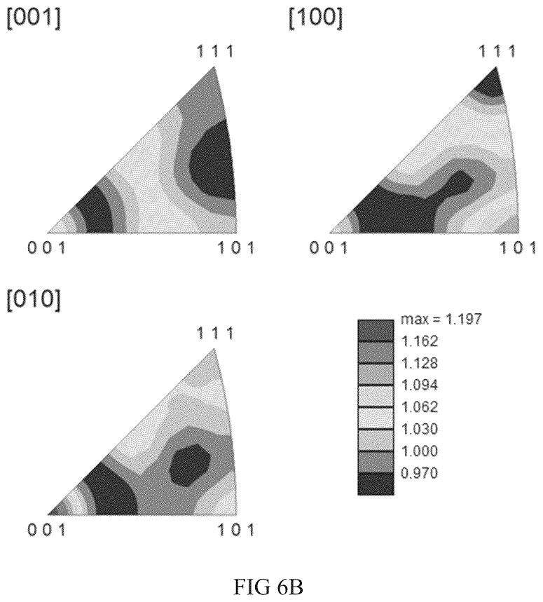

The sample texture was measure by EBSD. FIG. 6A is the pole figure plot. FIG. 6B is the inverse pole figure plot. FIGS. 5A and 5B show that there is no preferred texture in the 60W25Si15N sample.

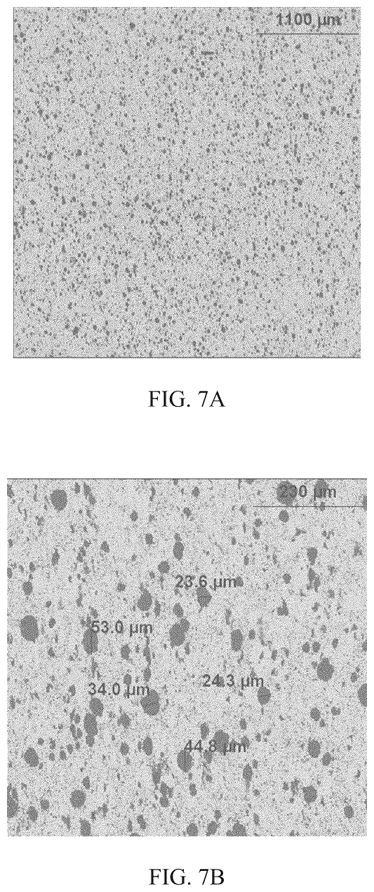

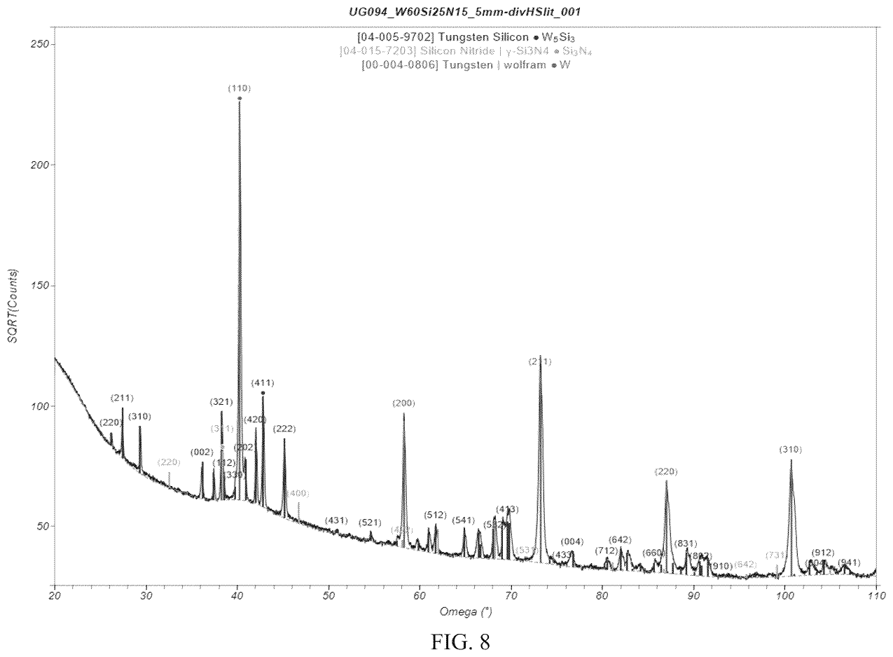

SEM images in FIGS. 7A and 7B show the microstructure of the sample. The SEM images suggest that the alloy has two phases, a W-enriched phase and a Si-enriched phase. The matrix of the alloy is the W-enriched phase. The average size of the Si-enriched phase was measured to be about 20-30 μm. To identify the phases, X-Ray Diffraction analysis was conducted on the sample. FIG. 8 is the phase identification results for sample 60W25Si15N (at %). The results show that sample has mainly two phases, cubic tungsten and tetragonal tungsten silicide W5Si3 phase. Besides these two phases, there is a minor amount of cubic silicon nitride (γ-Si₃N₄) phase. Table 3 shows that the weight concentration of tungsten phase, tungsten silicide and silicon nitride phase are 56.2%, 43.8 and less than 0.1%, respectively.

TABLE 3
Phase Identification and Quantification Results

| Sample ID | Phases Identified | Concentration (±5 wt %) |
|---|---|---|
| W60Si25N15 | Tungsten•W | 56.2 |
| | Cubic, | |
| | W5Si3•Tungsten Silicon | 43.8 |
| | Tetragonal | |
| | γ-Si3N4•Silicon Nitride** | <0.1 |
| | Cubic, | |

Various modifications and additions can be made to the exemplary embodiments discussed without departing from the scope of the present invention. For example, while the embodiments described above refer to particular features, the scope of this invention also includes embodiments having different combinations of features and embodiments that do not include all of the above-described features.

What is claimed is:

1. A process for manufacturing a sputtering target assembly, the method comprising:
combining silicon powder, tungsten powder and silicon nitride powder to form a mixed powder;
vacuum hot pressing the mixed powder at a temperature at or below 1400° C. to form a semi-sintered part; and
hot isostatic pressing the semi-sintered part at a temperature of 1650° C. or greater and a pressure over 20 ksi to form a sputtering target having a composition WₓSi_{100-x-y}N_{y} wherein x is 40-65 at. % and y is 10-30 at. %, and a density of at least 90% theoretical.

2. The process of claim 1, wherein a weight percentage of nitrogen in the mixed powder is within ±1% of a weight percentage of nitrogen in the sputtering target.

3. The process of claim 1, wherein a weight percentage of nitrogen in the mixed powder is within ±0.5% of a weight percentage of nitrogen in the sputtering target.

4. The process of claim 1, wherein a weight percentage of nitrogen in the mixed powder is within ±0.25% of a weight percentage of nitrogen in the sputtering target.

5. The process of claim 4, wherein a weight percentage of silicon and a weight percentage of tungsten in the mixed powder is within ±0.25% of a weight percentage of silicon and a weight percentage of tungsten in the sputtering target.

6. The process of claim 1 and further comprising bonding the sputtering target to a backing plate.

7. The process of claim 6 wherein bonding the sputtering target to the backing plate includes bonding the sputtering target to the backing plate by a solder bond.

8. A sputtering target assembly comprising:
a WₓSi_{100-x-y}N_{y} sputtering target wherein x is 40-65 at. % and y is 10-30 at. %, wherein the sputtering target has a density of at least 90% theoretical.

9. The sputtering target assembly of claim 8, wherein the WₓSi_{100-x-y}N_{y} sputtering target has a purity of at least 99.95%.

10. The sputtering target assembly of claim 8, wherein the WₓSi_{100-x-y}N_{y} sputtering target is bonded to a backing plate.

11. The sputtering target assembly of claim 10, wherein the backing plate is a copper or copper alloy backing plate.

12. The sputtering target assembly of claim 8, wherein the WₓSi_{100-x-y}N_{y} sputtering target is solder bonded to a backing plate.
